(19) United States
(12) Patent Application Publication
(10) Pub. No.: US 2018/0151210 A1
(43) Pub. Date: May 31, 2018

(54) SHARED SOURCE LINE ARCHITECTURES OF PERPENDICULAR HYBRID SPIN-TORQUE TRANSFER (STT) AND SPIN-ORBIT TORQUE (SOT) MAGNETIC RANDOM ACCESS MEMORY

(71) Applicant: Western Digital Technologies, Inc., Irvine, CA (US)

(72) Inventors: Shaoping LI, San Ramon, CA (US); Hong TSAI, Morgan Hill, CA (US)

(21) Appl. No.: 15/364,544

(22) Filed: Nov. 30, 2016

(51) Int. Cl. G11C 11/16; H01L 43/02; H01L 43/08; H01L 27/22

(52) U.S. Cl. CPC G11C 11/161; H01L 43/02; G11C 11/165; H01L 27/228; H01L 43/08

(57) ABSTRACT

The present disclosure relates to a hybrid spin-transfer torque (STT) and spin-bit torque (SOT) magnetic random access memory (MRAM). The cells of the hybrid STT-SOT MRAM has magnetic tunnel junctions (MTJs) with some ferromagnetic multilayers whose magnetization is oriented perpendicular to the plane of the substrate and some ferromagnetic multilayers whose magnetization is aligned within the plane of the substrate. The architecture results in high density memory. The hybrid STT-SOT MRAM lowers the programming current density while having a high switching speed higher thermal stability.

### BACKGROUND

### Field of the Disclosure

Embodiments of the present disclosure generally relate to hybrid spin-orbit torque (SOT) and spin-torque transfer (STT) magnetic random access memory (MRAM) devices.

### Description of the Related Art

MRAM technology offers non-volatility and fast response times, but a MRAM memory cell is limited in scalability and is susceptible to write disturbances. The programming current employed to switch between high and low resistance states across the MRAM magnetic layers is typically high. Thus, when multiple cells are arranged in an MRAM array, the programming current directed to one memory cell may induce a field change in the free layer of an adjacent cell. The potential for write disturbances, also known as the “half select problem,” can be addressed using a STT technique.

MRAM based magnetic tunnel junction (MTJ) storage devices are one of the most interesting candidates to address the “half select problem.” STT-MRAM gains a lot of attention as STT-MRAM is nonvolatile, scalable and has a low read access time. In STT-MRAM, the switching process occurs through the application of spin polarized current across the MTJ during programming. STT-MRAM has significant advantages over magnetic field switched MRAM. The main hurdles associated with magnetic field switched MRAM are the complex cell architecture, a high write current and poor scalability. Magnetic field switched MRAM cannot scale beyond the 65 nm process node. The poor scalability of such devices is intrinsic to the field writing methods. However, when spin polarized current is applied across the MTJ, it could generate some reliability issue for STT-MRAM.

To further mitigate the above mentioned issues, SOT-MRAM has been proposed. SOT-MRAM uses a three terminal MTJ based concept to isolate the read and write path compared to the two terminal concept of STT-MRAM. As a result, a SOT-MRAM chip could significantly improve read stability. Moreover, the write current could be much lower while the write access could be much faster because the write path can be optimized independently. Nonetheless, generally, SOT-MRAM has a large cell size and poor write selectivity because a SOT-M RAM device could overwrite many unselected cells during the write operation.

Therefore, what is needed is a MRAM device that has good scalability, good write access, low write current and a low read access time.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a schematic illustration of a memory array.

FIG. 2 is a schematic illustration of a memory cell.

FIGS. 3A-3D are schematic isometric illustrations of hybrid STT-SOT MRAM devices according to various embodiments.

FIGS. 4A and 4B are schematic illustrations of hybrid STT-SOT MRAM arrays according to various embodiments.

FIG. 4C is a schematic illustration of a circuit layout of a hybrid STT-SOT MRAM array.

FIGS. 5A and 5B are schematic cross-section illustrations of hybrid STT-SOT MRAM devices according to various embodiments.

FIG. 6 is a schematic illustration of a hybrid STT-SOT MRAM array layout according to one embodiment.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

The present disclosure generally relates to hybrid STT-SOT MRAM devices. The devices may include both an STT bitline that is coupled to a memory cell and an SOT bitline that may also be coupled to the memory cell. Within a STT-SOT MRAM array, a source line may be shared by two distinct STT-SOT MRAM devices to conserve space. Furthermore, the word lines in an array may be interleaved within a common plane.

The hybrid STT-SOT MRAM includes a MTJ connecting to a read bit line (i.e., STT bitline) to a source line through an isolation transistor in addition to a SOT bitline. The MTJ includes a ferromagnetic layer having a magnetic hard axis. In one embodiment, the shared SOT bitline and source line overlies the word bitline and is insulated from the word bitline and STT-bit lines. The MTJ is switchable between a first, relatively high resistance state and a second, relatively low resistance state. During the writing process, an assisted current through the bitline may also generate a magnetic torque in the ferromagnetic layer, independently of a SOT effect for assisting switching of the MTJ between the first and second states. Additionally, in some embodiments, the hybrid STT-SOT MRAM architecture has a small cell size, ˜6F², accommodating the highest density of the memory of this type.

Furthermore, the memory cell may include a composite fixed layer stack (i.e., pinned magnetic layer) formed on top of a substrate, a tunnel layer formed upon the fixed layer stack and a composite free layer stack (i.e., free magnetic layer) formed upon the tunnel barrier layer, and spin-polarizer stack. In one embodiment, the magnetization directions of each of the composite free layer and fixed layer are substantially perpendicular to the plane of the substrate while the magnetization directions of an assisted layer (i.e., bias affecting layer) are aligned along the in-plane direction of the substrate. In one embodiment, the free layer stack has perpendicular anisotropy and the longitudinal assisted layers are used to make the free layer switching process deterministic.

The terms “over,” “under,” “between,” and “on” as used herein refer to a relative position of one layer with respect to other layers. As such, for example, one layer disposed over or under another layer may be directly in contact with the other layer or may have one or more intervening layers. Moreover, one layer disposed between layers may be directly in contact with the two layers or may have one or more intervening layers. In contrast, a first layer “on” a second layer is in contact with the second layer. Additionally, the relative position of one layer with respect to other layers is provided assuming operations are performed relative to a substrate without consideration of the absolute orientation of the substrate.

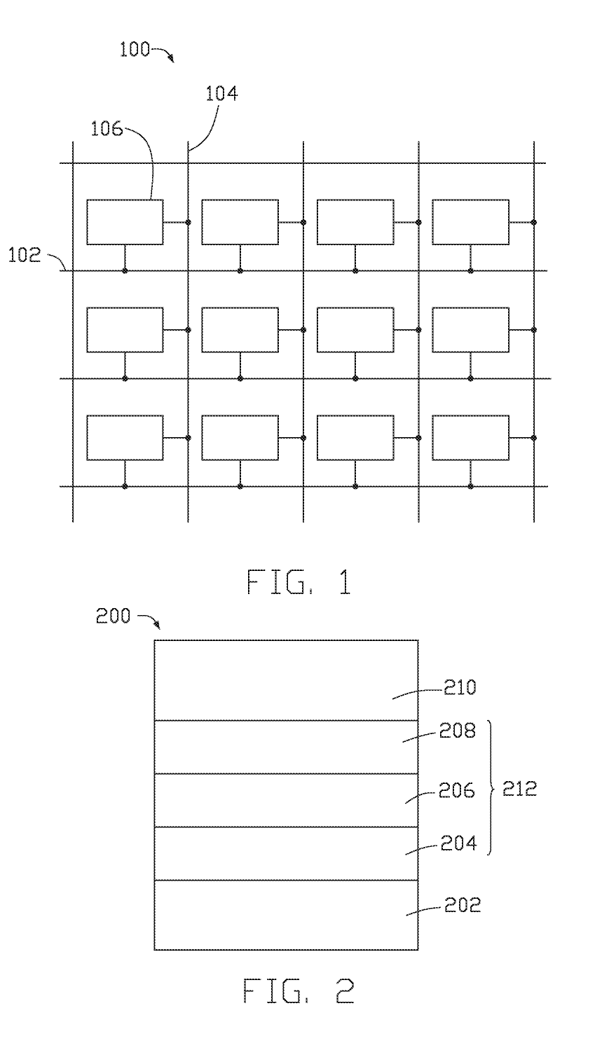

FIG. 1 is a schematic illustration of a memory array 100. The array 100 includes a plurality of a plurality of bitlines 102, 104 that are used to address the various memory devices 106 within the array 100.

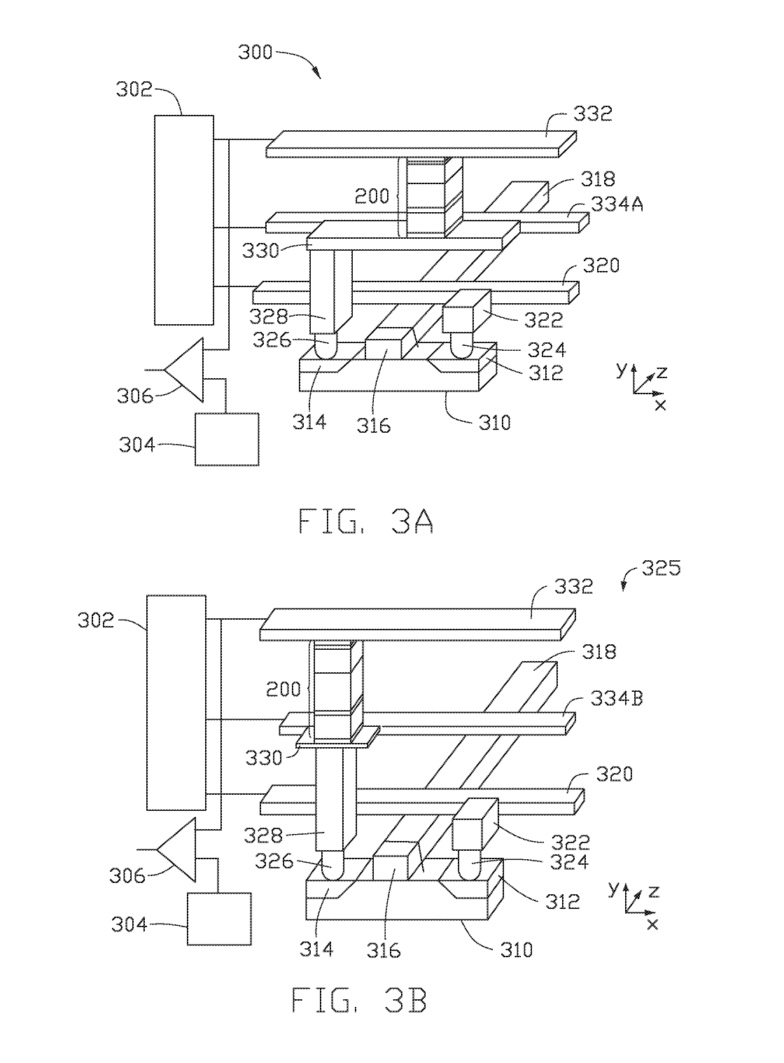

FIG. 2 is a schematic illustration of a memory cell 200 of a memory device 106. The memory cell 200 includes an SOT material layer 202, a free magnetic layer 204, an insulating layer 206, a pinned magnetic layer 208 and an antiferromagnetic (AFM) layer 210. The free magnetic layer 204, insulating layer 206 and pinned magnetic layer 208 comprise a MTJ 212. The insulating layer 206 comprises an insulating material such as MgO. It is to be understood that other materials are contemplated for the insulating layer 206 as well. The SOT material layer 202 may comprise Pt, Ta, W, Cu doped with either Bi or Ir, or combinations thereof. The free magnetic layer 204 and the pinned magnetic layer 208 may comprise Co, Fe, B, Co, CoFe, CoFeB, NiFe, CoHf or combinations thereof. The antiferromagnetic layer 210 may comprise Pt, Ir, Rh, Ni, Fe, Mn, or combinations thereof such as PtMn, PtPdMn, NiMn or IrMn. As will be discussed below, a bias affecting layer with the fixed longitudinal magnetization direction is put on the top of the memory cell, which make the switching more deterministic.

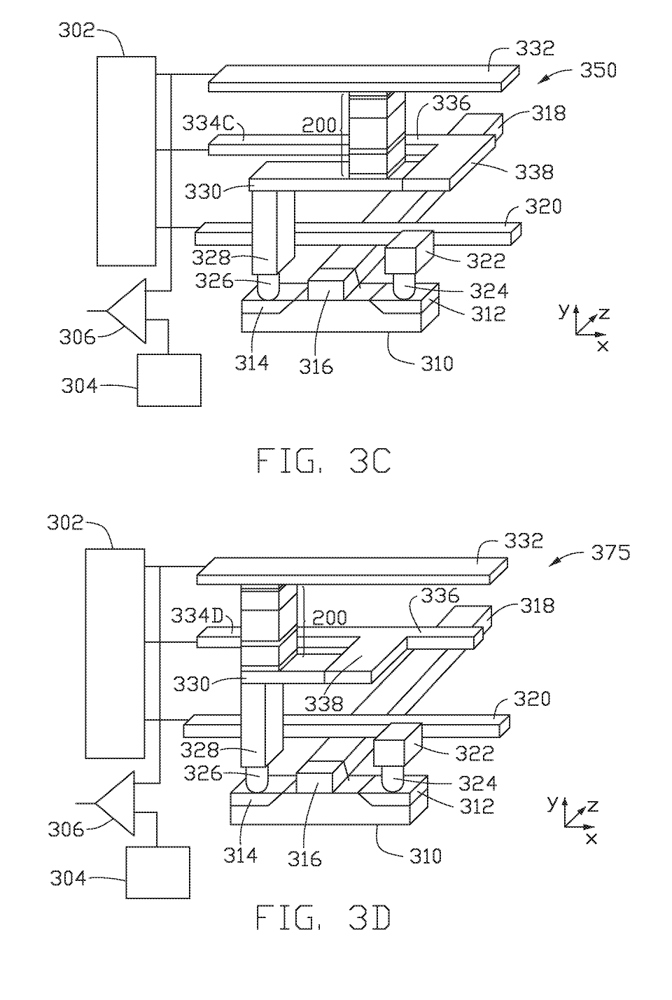

FIGS. 3A-3D are schematic isometric illustrations of hybrid STT-SOT MRAM devices 300, 325, 350, 375 according to various embodiments. The devices 300, 325, 350, 375 include sense/write/read circuitry 302, a reference cell 304 and an amplifier 306. The cell 304 and the circuitry 302 are coupled to the amplifier 306.

The devices 300, 325, 350, 375 also include an insulating material 310 having a source electrode 312 and a drain electrode 314 disposed therein. A gate electrode 316 is disposed over the insulating material 310. When current is applied to the source electrode 312 and the gate electrode 316, current flows through a semiconductor layer (not shown) to the drain electrode 314. Current is applied to the gate electrode 316 by the word line 318. Current is applied to the source electrode 312 through a source line 320. The source line 320 is disposed in a separate plane from the word line 318, and the source line 320 extends perpendicular to the word line 318. Various connection items 322, 324 are shown to connect the source electrode 312 to the source line 320. It is to be understood that more or less connection items 322, 324 may be present to connect the source electrode 312 to the source line 320 and the two connection items 322, 324 shown are merely one possibility.

The drain electrode 314 is coupled to the memory cell 200 through connection items 326, 328. It is to be understood that while two connection items 326, 328 are shown, more or less connection items 326, 328 may be present. A SOT layer 330 is present between the connection item 328 and the memory cell 200. An STT bitline 332 is coupled to another end of the memory cell 200. As shown in FIGS. 3A-3D, the STT bitline 332 is disposed in a separate plane from the source line 320 and extends substantially parallel to the source line 320 yet substantially perpendicular to the word line 318.

In FIGS. 3A and 3D, the memory cell 200 is vertically aligned in the “Y” axis with the drain electrode 314 and the connection items 328, 328. In FIGS. 3B and 3C, the memory cell 200 is vertically offset from the drain electrode 314 and connection items 326, 328 so that the memory cell 200 is not vertically aligned (i.e., is vertically offset) in the “Y” direction with the drain electrode 314 and connection items 326, 328.

A SOT bitline 334A-334D is also present. The SOT bitlines 334A-334D are all disposed within the same plane as the SOT layer 330 and are parallel to both the SOT layer 330, the STT bitline 332 and the source line 320. In FIGS. 3A and 3B, the SOT bitlines 334A-334B are flush against the SOT layer 330 so that there is no gap in the “X” direction between the SOT bitlines 334A-334B and the SOT layer 330. In FIGS. 3C and 3D, the SOT bitline 334C, 334D are partially spaced from the SOT layer 330. The SOT bitlines 334C, 334D each have a longitudinal portion 336 that extends in the “X” direction substantially parallel to the source line 320. The longitudinal portion 336 is spaced from the SOT layer 330. The SOT bitlines 334C, 334D have a branch portion 338 that is coupled between the SOT layer 330 and the longitudinal portion 336. The branch portion 338 extends substantially parallel to the word line 318. In one embodiment, the longitudinal portion 336, the branch portion 338 and the SOT layer 330 are all disposed within the same plane.

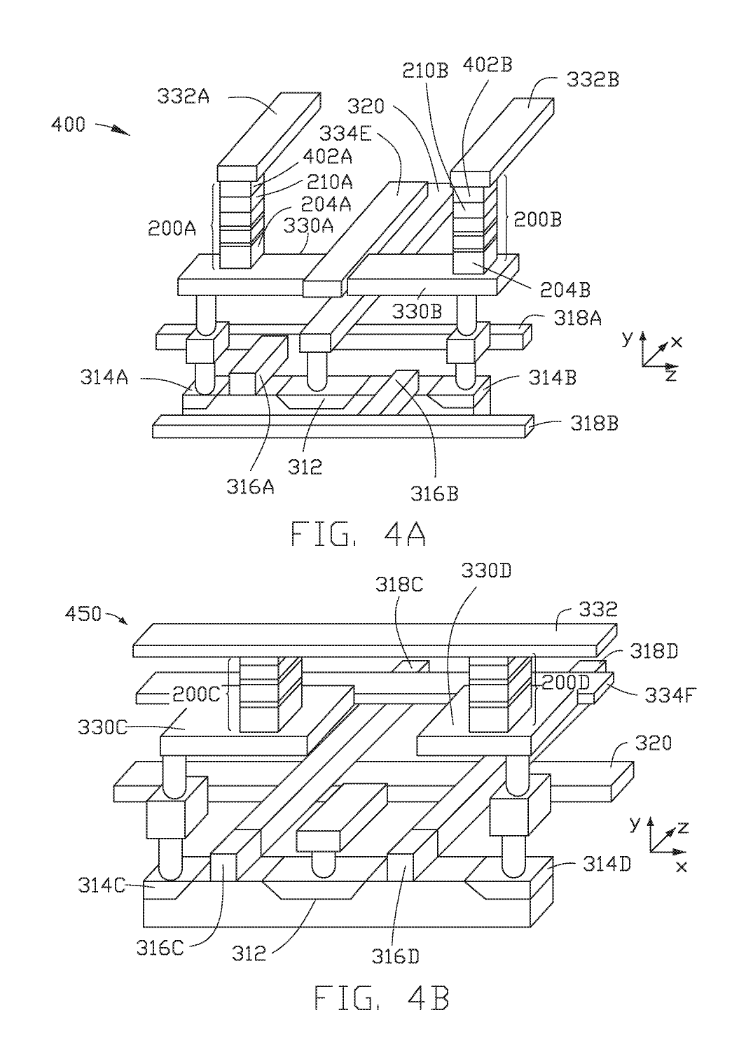

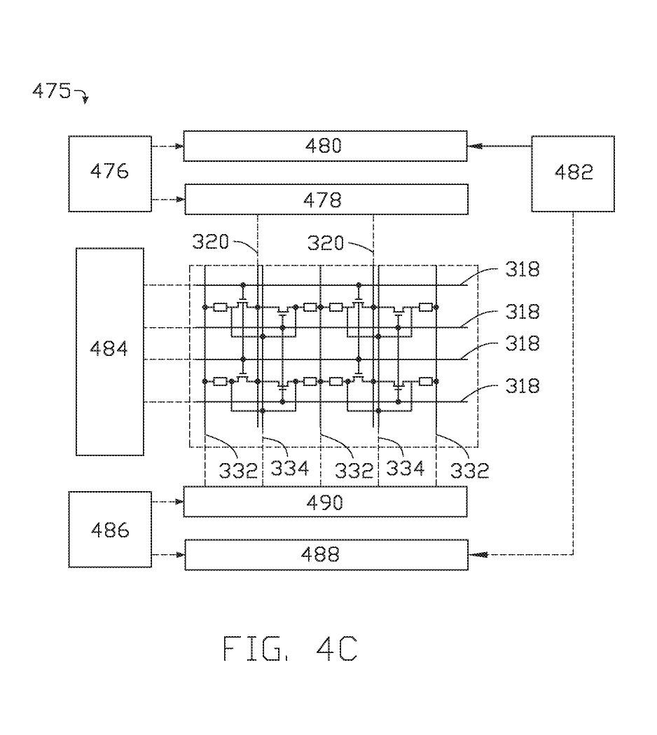

FIGS. 4A and 4B are schematic illustrations of hybrid STT-SOT MRAM arrays 400, 450 according to various embodiments. In one embodiment, an array includes column selection circuitry coupled to first and second ends of the source lines and to a first end of the bitlines and is configured to select a specific bitline. Global bias circuitry is configured to provide a plurality of timed bias voltages. Sense amplifiers and write drivers circuitry are coupled between the column selection circuitry and the global bias circuitry. According to one embodiment, the sense amplifiers and write drivers circuitry are configured to receive the timed bias voltages; apply a read voltage across the source line and the read bit line coupled to a memory cell on the selected read bit line (STT-bit line); apply a write current on the SOT bit line in a first direction through the memory cell to write a first state; reapply the read voltage across the source line and the read bit line; and apply a programmable offset current to the read bit line. Some embodiments of the cell architectures disclosed herein can perform a hybrid STT/SOT write operation once both STT bitline and SOT bitline turn on simultaneously. Some embodiments of the hybrid STT-SOT MRAM disclosed herein lower the programming current density while having a high switching speed higher thermal stability.

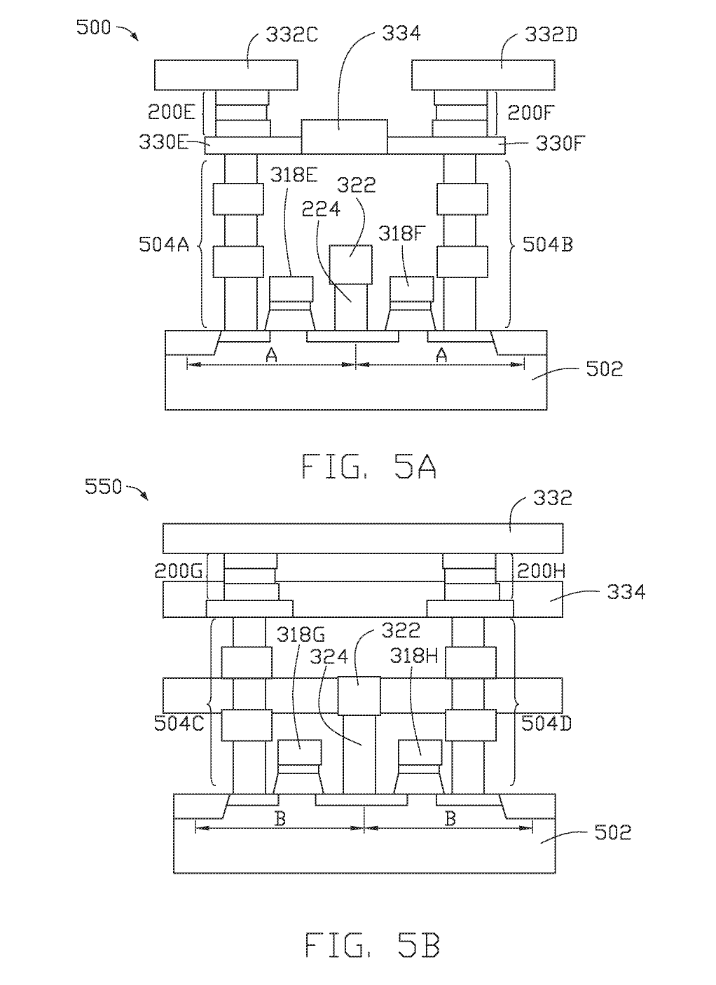

In FIG. 4A, the array 400 includes drain electrodes 314A, 314B that share a common source electrode 312 and source line 320 while still having distinct gate electrodes 316A, 316B. The gate electrodes 316A, 316B have separate, distinct word lines 318A, 318B that are interleaved. FIG. 4A shows a single SOT bitline 334E with SOT layers 330A, 330B coupled thereto, but it is to be understood that while not shown in FIGS. 5A and 5B, the SOT bitline 334E may have a longitudinal portion as well as a branch portion as shown and described with regards to FIGS. 3C and 3D. The memory cells 200A, 200B each are coupled to separate and distinct STT bitlines 332A, 332B. Within the memory cells, the free layer 204A, 204B are magnetized perpendicular to the plane of the SOT layers 330A, 330B. Furthermore, there is a bias affecting layer 402A, 402B in each memory cell 200A, 200B that is disposed between the AFM layer 210A, 210B and the STT bitlines 332A, 332B. The bias affecting layer 402A, 402B may comprise Co, Fe, B, Co, CoFe, CoFeB, NiFe, CoHf or combinations thereof and is magnetized perpendicular to the free layers 204A, 204B. The bias affecting layer 402A, 402B is magnetic with a fixed longitudinal magnetization direction which makes the SOT switching more deterministic. The bias affecting layers 402A, 402B increase the switching speed of the free layer 204A, 204B and makes the switching more deterministic. Additionally, in the dual cell 200A, 200B stack, the bias affecting layers 402A, 402B magnetization directions are the same to enhance stability. In the embodiment shown in FIG. 4A, memory cell 200A is vertically offset from the drain electrode 314A while memory cell 200B is vertically aligned with the drain electrode 314B. It is to be understood that any configuration or combination of configurations for the memory cells (in terms of vertical alignment/offset) that is disclosed in FIGS. 3A-3D is applicable to the memory arrays in FIGS. 4A and 4B. Furthermore, it is to be understood that any configuration or combination of configurations for the SOT bitline (in terms of longitudinal portions and branches) that is disclosed in FIGS. 3A-3D is applicable to the memory arrays in FIGS. 4A and 4B.

In regards to FIG. 4B, the SOT layers 330C, 330D are coupled to the SOT bitline 334F and the memory cells 200C, 200D are shown to be vertically aligned with the drain electrodes 314C and vertically offset from the drain electrodes 314D, respectively. Additionally, the word lines 318C, 318D are not interleaved in FIG. 4B.

FIG. 4C is a schematic illustration of a circuit layout of a hybrid STT-SOT MRAM array 475 according to one embodiment. The circuit layout shows a column circuit drive 476 that is coupled to column selection circuitry 478. Both the column selection circuitry 478 and the column circuit drives are connected to a reference sense amplifier circuitry 480. The reference sense amplifier is coupled to global bias circuitry 482. Word line circuitry 484 is coupled to the word lines 318 while column circuit drives 486 are coupled to both sense amplifiers and write drive-ins 488 and column selection circuitry 490. The column selection circuitry 490 is coupled to both the column circuit drives 486 and the sense amplifiers and write drive-ins 488. The global bias circuitry 482 is coupled to the sense amplifiers and write drive-ins 488. In FIG. 4C, an SOT-MRAM bitcell array 475 is coupled to the first, second and third column selection circuitry 478 and to the word line circuitry 484. The first, second and third sense amplifiers and write drivers circuitry are coupled to the first, second and third column selection circuitry 478 respectively. For simplicity and brevity, other known circuit blocks in a memory, such as data storage latches, address decoders and timing circuity are not shown.

FIGS. 5A and 5B are schematic cross-section illustrations of hybrid STT-SOT MRAM devices 500, 550 according to various embodiments. The devices 500, 550 include the word lines 318E-318H, memory cells 200E-200H, SOT layers 330E, 330F and connection items 504A-504D. The width of an individual hybrid STT-SOT MRAM device, shown in FIG. 4A by arrows “A” with each distance between the center of the source electrode and the edge of the device is 3F. Similarly, the length of an individual hybrid STT-SOT MRAM device, shown in FIG. 4B by arrows “B” between the center of the source electrode and the edge of the device is 2F. Therefore, the total footprint of a STT-SOT MRAM device is 6F².

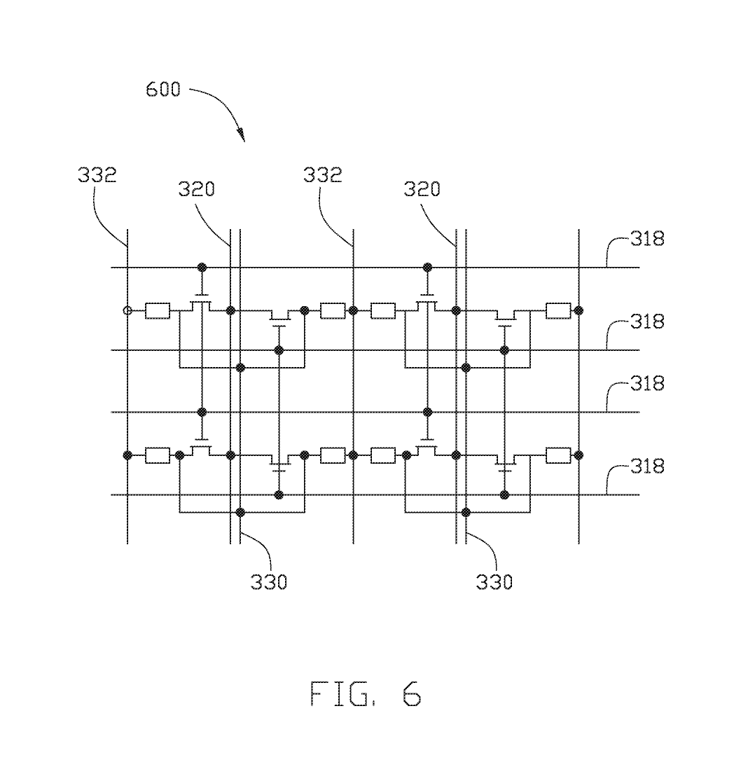

FIG. 6 is a schematic illustration of a STT-SOT hybrid MRAM array 600 layout according to one embodiment. FIG. 6 shows that the word lines 318 are perpendicular to the source lines 320, and the word lines 318 are perpendicular to the STT bitlines 332. Additionally, FIG. 6 shows that the word lines 318 are perpendicular to the SOT bitlines 334. Finally, FIG. 6 shows that the STT bitlines 332, the SOT bitlines 334 and the source lines 320 are all parallel.

In reading data from the memory cells 200, a read voltage is applied across a source line 320 and a STT bitline 332, then a write current is applied across the source line 320 and an SOT bitline 334, then the read voltage is reapplied to the source line 320 and STT bitline 332, and finally a programmable offset current is applied to either the source line 320 or the STT bitline 332.

According to one embodiment, to read data from each of a plurality of memory cells in a memory array, a read voltage is applied across a magnetic tunnel junction within a memory cell; a current through the magnetic tunnel junction under the applied read voltage into a sample voltage is converted; the sample voltage in a capacitor is stored; a write current through the bottom layer of the magnetic tunnel junction to reset the memory cell to a memory state through SOT effect is applied; the read voltage across the magnetic tunnel junction is reapplied; the stored voltage and a programmable offset current is used to create a current reference; the difference between the reference current and the current through the magnetic tunnel junction under the reapplied read voltage is converted to generate an evaluation voltage; and the sample voltage and the evaluation voltage are compared.

While the foregoing is directed to embodiments of the present disclosure, other and further embodiments of the disclosure may be devised without departing from the basic scope thereof, and the scope thereof is determined by the claims that follow.

1. A hybrid spin-torque transfer spin-orbit torque (STT-SOT) memory device, comprising:
a word line;
a gate electrode coupled to an insulating material and the word line;
a source line coupled to a source electrode;
a drain electrode;
a memory cell coupled to the drain electrode;
a SOT bitline; and
a STT bitline coupled to the memory cell, wherein the source line, the SOT bitline and the STT bitline are all disposed in separate planes and are parallel to each other.

2. The device of claim 1, further comprising a SOT layer coupled to the SOT bitline, the memory cell and the drain electrode.

3. The device of claim 2, wherein the SOT layer is disposed within the same plane as the SOT bitline.

4. The device of claim 3, wherein the SOT bitline includes a longitudinal portion and a branch portion.

5. The device of claim 4, wherein the branch portion is coupled to the SOT layer.

6. The device of claim 5, wherein the longitudinal portion is spaced from the SOT layer.

7. The device of claim 6, wherein the memory cell and the drain electrode are vertically aligned.

8. The device of claim 6, wherein the memory cell is vertically offset from the drain electrode.

9. The device of claim 1, wherein the memory cell and the drain electrode are vertically aligned.

10. The device of claim 1, wherein the memory cell is vertically offset from the drain electrode.

11. The device of claim 1, wherein the memory cell includes a free layer that is magnetized perpendicular to the bitlines.

12. A hybrid STT-SOT memory device, comprising:
a first word line;
a first gate electrode coupled to an insulating material and the first word line;
a second word line;
a second gate electrode coupled to the second word line and the insulating material;
a source line coupled to a source electrode;
a first drain electrode;
a second drain electrode;
a first memory cell coupled to the first drain electrode;
a second memory cell coupled to the second drain electrode;
a SOT bitline; and
a STT bitline coupled to the first memory cell and the second memory cell, wherein the first word line and the second word line are interleaved within the same plane.

13. The device of claim 12, further comprising a first SOT layer coupled to the SOT bitline, the first memory cell and the first drain electrode.

14. The device of claim 13, wherein the first SOT layer is disposed within the same plane as the SOT bitline.

15. The device of claim 14, wherein the SOT bitline includes a longitudinal portion and a first branch portion.

16. The device of claim 15, wherein the first branch portion is coupled to the first SOT layer.

17. The device of claim 16, wherein the longitudinal portion is spaced from the first SOT layer.

18. The device of claim 15, further comprising a second SOT layer coupled to the SOT bitline, the second memory cell and the second drain electrode.

19. The device of claim 18, wherein the second SOT layer is disposed within the same plane as the SOT bitline.

20. The device of claim 19, wherein the SOT bitline includes a second branch portion.

21. The device of claim 20, wherein the second branch portion is coupled to the second SOT layer.

22. The device of claim 21, wherein the longitudinal portion is spaced from the second SOT layer.

23. The device of claim 12, wherein the first memory cell and the first drain electrode are vertically aligned.

24. The device of claim 23, wherein the second memory cell is vertically offset from the second drain electrode.

25. The device of claim 12, wherein the first memory cell is vertically offset from the first drain electrode.

26. The device of claim 12, wherein the first memory cell includes a free layer that is magnetized perpendicular to the bitlines.

27. A hybrid STT-SOT memory device, comprising:
a first word line;
a first gate electrode coupled to an insulating material and the first word line;
a second word line;
a second gate electrode coupled to the second word line and the insulating material;
a source line coupled to a source electrode;
a first drain electrode;
a second drain electrode;
a first memory cell coupled to the first drain electrode;
a second memory cell coupled to the second drain electrode;
a SOT bitline; and
a STT bitline coupled to the first memory cell and the second memory cell, wherein the source line, the SOT bitline and the STT bitline are all disposed in separate planes and are parallel to each other.

28. The device of claim 27, further comprising a first SOT layer coupled to the SOT bitline, the first memory cell and the first drain electrode.

29. The device of claim 28, wherein the first SOT layer is disposed within the same plane as the SOT bitline.

30. The device of claim 29, wherein the SOT bitline includes a longitudinal portion and a first branch portion.

31. The device of claim 30, wherein the first branch portion is coupled to the first SOT layer.

32. The device of claim 31, wherein the longitudinal portion is spaced from the first SOT layer.

33. The device of claim 32, further comprising a second SOT layer coupled to the SOT bitline, the second memory cell and the second drain electrode.

34. The device of claim 33, wherein the second SOT layer is disposed within the same plane as the SOT bitline.

35. The device of claim 34, wherein the SOT bitline includes a second branch portion.

36. The device of claim 35, wherein the second branch portion is coupled to the second SOT layer.

37. The device of claim 36, wherein the longitudinal portion is spaced from the second SOT layer.

38. The device of claim 37, wherein the first memory cell and the first drain electrode are vertically aligned.

39. The device of claim 38, wherein the second memory cell is vertically offset from the second drain electrode.

40. The device of claim 27, wherein the first memory cell is vertically offset from the first drain electrode.

41. The device of claim 27, wherein the first memory cell includes a free layer that is magnetized perpendicular to the bitlines.
